(19) United States
(12) Patent Application Publication
(10) Pub. No.: US 2013/0186464 A1
(43) Pub. Date: Jul. 25, 2013

(54) BUFFER LAYER FOR IMPROVING THE PERFORMANCE AND STABILITY OF SURFACE PASSIVATION OF SILICON SOLAR CELLS

(71) Applicants: Shuran Sheng, Santa Clara, CA (US); Lin Zhang, San Jose, CA (US)

(72) Inventors: Shuran Sheng, Santa Clara, CA (US); Lin Zhang, San Jose, CA (US)

(21) Appl. No.: 13/733,825

(22) Filed: Jan. 3, 2013

Related U.S. Application Data
(60) Provisional application No. 61/582,698, filed on Jan. 3, 2012.
(60) Provisional application No. 61/666,533, filed on Jun. 29, 2012.

(51) Int. Cl. H01L 31/0216; H01L 31/18

(52) U.S. Cl. CPC H01L 31/02167; H01L 31/02168; H01L 31/18
USPC 136/256; 118/729; 438/57

(57) ABSTRACT

Embodiments of the present invention generally relate to the fabrication of solar cells and more specifically to a buffer layer for improving the performance and stability of surface passivation of Si solar cells. Generally, a passivation layer stack containing a buffer layer (interlayer) is formed on a surface of the silicon-based substrate. In one embodiment, the passivation layer stack may be formed on the back surface of the substrate. In another embodiment, the passivation layer stack is formed on the back surface of the substrate and a front emitter region (light receiving surface) of the substrate.

### CROSS-REFERENCE TO RELATED APPLICATIONS

This application claims benefit of U.S. provisional patent application Ser. No. 61/582,698, filed Jan. 3, 2012, and U.S. provisional patent application Ser. No. 61/666,533, filed Jun. 29, 2012 both of which are herein incorporated by reference.

### BACKGROUND OF THE INVENTION

1. Field of the Invention

Embodiments of the present invention generally relate to the fabrication of solar cells and more specifically to a buffer layer for improving the performance and stability of surface passivation of silicon solar cells.

2. Description of the Related Art

Solar cells are photovoltaic devices that convert sunlight directly into electrical power. The most common solar cell material is silicon, which is in the form of single, polycrystalline, multi-crystalline substrates, or amorphous films. Efforts to reduce the cost of manufacturing solar cells, and thus the cost of the resulting cell, while maintaining or increasing the overall efficiency of the solar cell produced are ongoing.

More specifically, photovoltaic (PV) or solar cells are devices which convert sunlight into direct current (DC) electrical power. A typical PV cell includes a p-type silicon wafer, or substrate, typically less than about 0.3 mm thick, with a thin layer of an n-type silicon material disposed on top of the p-type substrate. The generated voltage, or photo-voltage, and generated current by the PV cell are dependent on the material properties of the p-n junction, the interfacial properties between deposited layers, and the surface area of the device. When exposed to sunlight (consisting of energy from photons), the p-n junction of the PV cell generates pairs of free electrons and holes. An electric field formed across a depletion region of the p-n junction separates the free electrons and holes, creating a voltage. A circuit from n-side to p-side allows the flow of electrons when the PV cell is connected to an electrical load. Electrical power is the product of the voltage times the current generated as the electrons and holes move through the external electrical load and eventually recombine. Each solar cell generates a specific amount of electrical power. A plurality of solar cells is tiled into modules sized to deliver the desired amount of system power.

The efficiency at which a solar cell converts incident light energy into electrical energy is adversely affected by a number of factors, including the fraction of incident light that is reflected off the light receiving surface of a solar cell and/or not reflected off the back surface of a solar cell, and the recombination rate of electrons and holes in a solar cell. When electrons and holes recombine, the incident solar energy is re-emitted as heat or light, thereby lowering the conversion efficiency of the solar cells. Recombination may occur in the bulk silicon of a substrate, which is a function of the number of defects in the bulk silicon, or on the front or back surface of a substrate, which is a function of how many dangling bonds, i.e., unterminated chemical bonds (manifesting as trap sites), are on the substrate surface. Dangling bonds are typically found on the surface of the substrate because the silicon lattice of substrate ends at the front or back surface. These dangling bonds act as defect traps and therefore are sites for recombination of electron-hole pairs.

The efficiency of a solar cell may be enhanced by use of a passivation layer on the back surface of a solar cell. A good passivation layer can provide a desired film property that reduces recombination of the electrons or holes in the solar cells, and redirects electrons and charges back into the solar cells to generate photocurrent. Furthermore, the passivation layer may also serve as a backside reflector to minimize light absorption while assisting in reflecting light back to the solar cell devices.

In order to passivate an n-type emitter surface for a p-type base solar cell, a back p-type Si surface for a p-type base solar cell or a p-type emitter surface for an n-type base solar cell, a passivation layer, such as an aluminum oxide (such as Al₂O₃) layer may be formed on the back surface of the silicon substrate. Aluminum oxide is not only effective in passivating the dangling bonds, but also has effective fixed charge to improve field effect passivation. A silicon nitride (SiN) layer may be further deposited on the aluminum oxide layer to prevent the aluminum oxide from reacting with a later-deposited (e.g., screen printed) metal back contact material (e.g., Al paste) during the subsequent high-temperature anneal process, sometimes referred to as a firing process. However, problems arise at the interface between the aluminum oxide layer and the silicon nitride layer. For example, the interface displays less than desirable thermal and mechanical stress stability, charge instability, and is subject to cross-contamination between the aluminum oxide and silicon nitride depositions. Also, a large amount of aluminum oxide is required to provide desired solar cell performance characteristics, which suffers from a generally low deposition rate and ultimately reduces throughput. Moreover, difficulties are often experienced in subsequent laser ablation and back surface field (BSF) formation due to the aforementioned characteristics of the interface between the aluminum oxide and silicon nitride layers. Therefore, there is a need in the art for improved passivation of solar cells, more specifically an improved layer stack that reduces or eliminates the aforementioned challenges.

In addition to the challenges of solar cell passivation, cost effective manufacturing of solar cells with passivation layers is a continual struggle. Manufacturing high efficiency solar cells at low cost is the key for making solar cells more competitive for the generation of electricity for mass consumption. The efficiency of solar cells is directly related to the ability of a cell to collect charges generated from absorbed photons in the various layers. Good front surface and rear surface passivation layers can help to reduce the recombination of the generated electrons or holes in the formed solar cell device, and redirect electrons and holes back into the solar cells to generate a desirable photocurrent. When electrons and holes recombine, the incident solar energy is re-emitted as heat or light, thereby lowering the conversion efficiency of the solar cells. Also, in general, a passivation layer will have desirable optical properties to minimize light reflection and absorption as light passes through the passivation layer, and desirable functional properties to “surface” passivate the surface(s) it is disposed over, “bulk” passivate the adjacent regions and surface of the substrate, and store a desired charge to “field” passivate the solar cell substrate surface that it is disposed over. The formation of a desirable passivation layer on a solar cell can greatly improve the efficiency of the solar cell, yet, the refractive index (n) and the inherent extinction coefficient (k) of the formed front side passivation layer(s) needs to be tuned with the surrounding layers to minimize light reflection and enhance light absorption by the solar cell device. However, deposition rate, and thus the ultimate number of substrates which can be processed in a set period of time, has an effect on the index of refraction and k values, as well as the physical properties of the film, such as the density.

In order to meet these challenges, the following solar cell processing requirements generally need to be met: 1) the cost of ownership (CoO) for substrate fabrication equipment needs to be improved (e.g., high system throughput, high machine up-time, inexpensive machines, inexpensive consumable costs), 2) the area processed per process cycle needs to be increased (e.g., reduce processing per Wp) and 3) the quality of the formed layers and film stack formation processes needs to be well controlled and sufficient to produce highly efficient solar cells. Therefore, there is a need to cost effectively form and manufacture silicon sheets for solar cell applications.

Further, as the demand for solar cell devices continues to grow, there is a trend to reduce cost by increasing the substrate throughput and improving the quality of the deposition processes performed on the substrate. However, the cost associated with producing and supporting all of the processing components in a solar cell production line continues to escalate dramatically. To reduce this cost while also reducing surface contamination, there is a need for a design of a novel solar cell processing system and processing sequence that has a high throughput, improved device yield, reduced number of substrate handling steps, and a compact system footprint.

### SUMMARY OF THE INVENTION

Embodiments of the present invention generally relate to a solar cell device comprising an emitter region formed on a first surface of a substrate, which has a conductivity type opposite to a conductivity type of the substrate. The solar cell also comprises one or more passivation layer stacks. The passivation layer stack(s) comprises a first dielectric layer formed on the second surface of the substrate or the emitter region, a second dielectric layer formed over the first dielectric layer, and an interlayer disposed between the first dielectric layer and the second dielectric layer.

Certain embodiments of the present invention generally relate to a method of manufacturing a solar cell device. The method is performed by forming one or more passivation layer stacks on a first surface of a substrate in a processing chamber. The passivation layer stack(s) are made by forming a first dielectric layer of aluminum oxide on the first surface of the substrate. Next, an interlayer if formed over the first dielectric layer. Finally, a second dielectric layer of silicon nitride is formed over the interlayer.

Other embodiments of the present invention generally relate to a solar cell processing system. A substrate automation system is provided having one or more conveyors that are configured to transfer substrates serially through a processing region in a first direction. The processing region is generally maintained at a pressure below atmospheric pressure. A first processing chamber is provided having a first deposition source configured to deliver a processing gas comprising an aluminum containing precursor and an oxygen containing precursor to a surface of each of the substrates and a second deposition source configured to deliver a silicon containing precursor and an oxygen containing precursor to a surface of each of the substrates as the substrates are transferred through the processing region relative to the two or more first deposition sources. A second processing chamber is provided having a first deposition source configured to deliver a processing gas of a silicon containing precursor, a nitrogen containing precursor, and oxygen containing precursor to a surface of each of the substrates as the substrates are transferred through the processing region relative to the first deposition source.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1C are schematic cross-sectional views that illustrate a solar cell device during different stages of a processing sequence shown in FIG. 2 according to various embodiments of the present invention;

FIG. 2 depicts a process flow diagram illustrating a processing sequence of forming a solar cell device according to the embodiments shown in FIGS. 1A-1C;

FIG. 3 is a schematic cross-sectional view of a solar cell device formed according to a method described herein and utilizing a processing system described herein according to certain embodiments of the present invention;

FIG. 4 is a schematic isometric view of one embodiment of a substrate processing system according to certain embodiments of the present invention; and

FIG. 5 is a schematic side cross-sectional view of a deposition chamber according to certain embodiments of the present invention.

### DETAILED DESCRIPTION

Embodiments of the present invention generally relate to the fabrication of solar cells and more specifically to the formation of a buffer layer that is used to improve the performance and stability of the surface passivation of a silicon (Si) solar cell. Generally, a passivation layer stack containing a buffer layer (or interlayer) is formed on a surface of the silicon-based substrate. In one embodiment, the passivation layer stack may be formed on the back surface of the substrate. In another embodiment, the passivation layer stack is formed on the back surface of the substrate and/or a front emitter region (light receiving surface) of the substrate. In one embodiment, the passivation layer stack includes an aluminum oxide layer, a buffer layer, and a silicon nitride layer. The aluminum oxide layer is about 200 Å thick and has a refractive index (n) of 1.6 to 1.8 at a wavelength of 633 nm, and the silicon nitride layer is deposited in a manner such that the silicon nitride is formed with a thickness of about 800 Å and a refractive index (n) of 1.8 to 2.1 at a wavelength of 633 nm. The interlayer is formed between the aluminum oxide layer and the silicon nitride layer, and may have a thickness of about 50-100 Å, resulting in a total passivation layer stack thickness of about 1050 Å to about 1100 Å.

In one embodiment, the interlayer may comprise silicon dioxide or silicon oxynitride. The use of the interlayer, comprising either silicon dioxide or silicon oxynitride, acts as a barrier layer and reduces the thickness of the underlying aluminum oxide layer required to form a passivation layer stack that has desirable passivation, physical, electrical and optical properties that will help to improve the solar cell's device performance. The reduction in the amount of aluminum oxide required to form the passivation layer stack will reduce the production cost of the solar cell device, due to a reduction in the amount of the often expensive precursors used to form the aluminum oxide layer and the relatively inexpensive cost of forming the interlayer layer. Increased overall throughput of a processing system can also be achieved by following the processes described herein, since the deposition rate of aluminum oxide is relatively slow and the addition of the interlayer layer reduces the amount of aluminum oxide that needs to be deposited on the substrate.

The interlayer also provides optical properties similar to the aluminum oxide layer, such as the index of refraction (n≈1.7) which can improve the overall efficiency of the solar cell. In addition, due to similarities between silicon dioxide/silicon oxynitride and aluminum oxide such as thermal and sheer stress, thermal and mechanical stability of the passivation stack can be improved. Cross-contamination due to moisture, metal, and/or ion migration between the aluminum oxide and silicon nitride layers are also reduced by the interlayer which acts as a barrier to prevent the aforementioned cross-contamination. In addition to acting as a barrier, the interlayer can also enhance the performance of passivation of the underlying aluminum oxide layer through stress and/or charge modulation due to the fact that the interlayer posses low stress and a low density of fixed charge. As a result of the improved matching of optical properties (i.e. index of refraction) between the aluminum oxide layer and the interlayer and the reduction in thickness of the aluminum oxide, laser ablation and BSF formation may be improved. However, when the interlayer is thin, such as less than 20 nm, refractive index matching may not be an important consideration. The similar indices of refraction between the interlayer and aluminum oxide will improve the laser ablation process, because the ability of the delivered laser energy to effectively and efficiently remove the ablated material is affected by the optical properties of the material that is being removed. Generally, similar optical properties between two different materials will result in greater precision by which the laser ablation process may be performed, which may result in a laser ablated feature that has an improved feature shape and minimally damaged underlying substrate material.

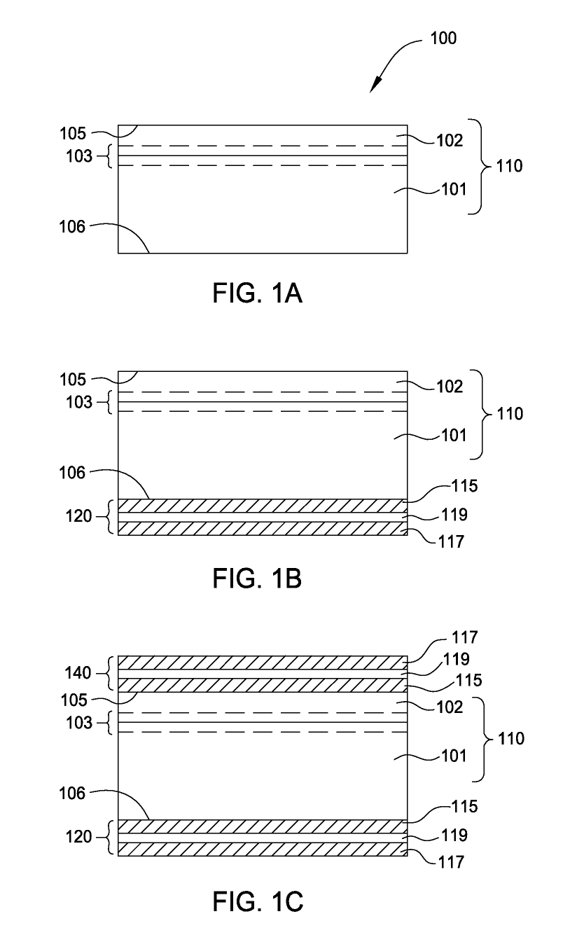

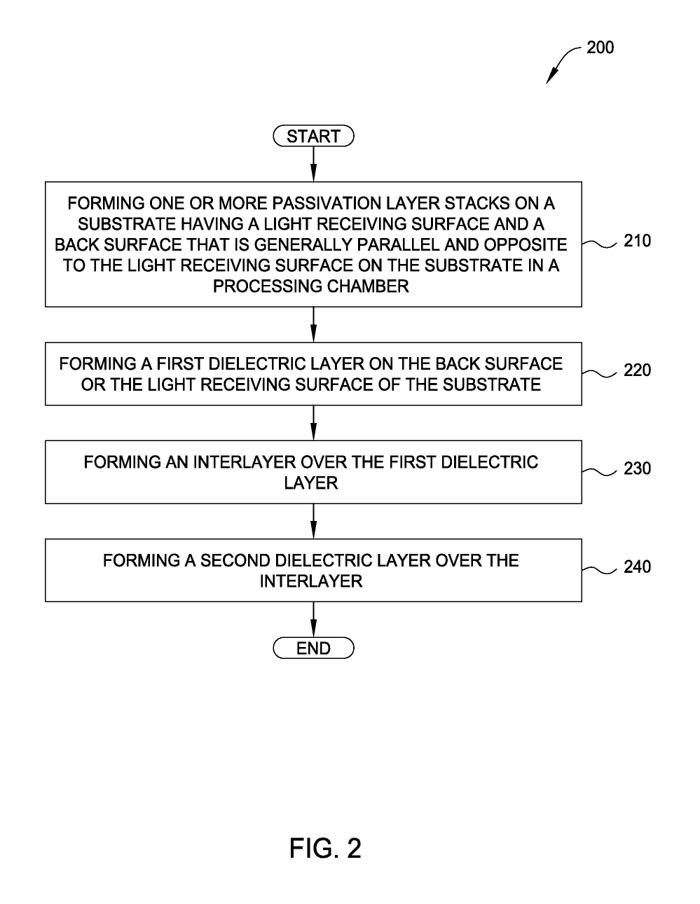

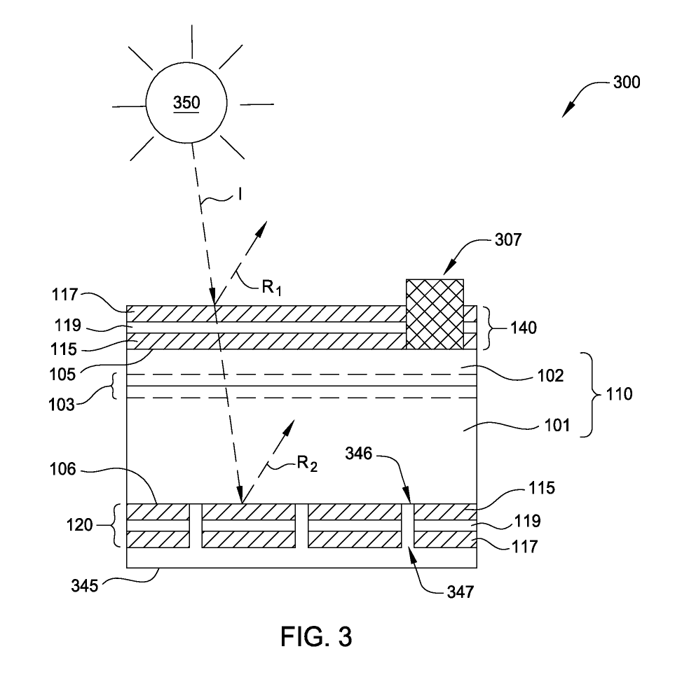

FIGS. 1A-1C are schematic cross-sectional views that illustrate a solar cell device during different stages of a solar cell processing sequence shown in FIG. 2 according to various embodiments of the present invention. FIG. 3 is a schematic cross-sectional view of a solar cell device that contains an interlayer within one of the passivation layer stacks, which may be formed according to the method steps illustrated and described in relation to FIGS. 1 and 2. The method steps described herein may also be performed in a processing system described hereinafter according to certain embodiments of the present invention.

Referring to FIG. 3, in one embodiment, the formed solar cell substrate 110 has a passivation layer stack 140 on a front surface (e.g., top surface 105) of a formed solar cell device 300, front side electrical contacts 307, a rear surface passivation layer stack 120 on a rear surface (e.g., rear surface 106) and a conductive layer 345 that forms rear side electrical contacts 346 that electrically contact the surface of the substrate 310 through via regions 347 formed in the passivation layer stack 120. In one embodiment, a substrate 110 comprises a silicon substrate that has a p-type dopant disposed therein to form part of the solar cell device 300, which is further discussed below. In this configuration, the substrate 310 may have a p-type doped base region 101 and an n-doped emitter region 102 formed thereon, typically by a doping and diffusion/anneal process, although other processes including ion implant may be used. The substrate 110 also includes a p-n junction region 103 that is disposed between base region 101 and emitter region 102 of the solar cell, and the substrate 110 is the region in which electron-hole pairs are generated when solar cell device 300 is illuminated by incident photons “I” of light from the sun 350. The conductive layer 345 and front side electrical contacts 307 may comprise a metal, such as the aluminum (Al), silver (Ag), tin (Sn), cobalt (Co), nickel (Ni), zinc (Zn), lead (Pb), tungsten (W), titanium (Ti), tantalum (Ta), nickel vanadium (NiV), or other similar materials, and combinations thereof.

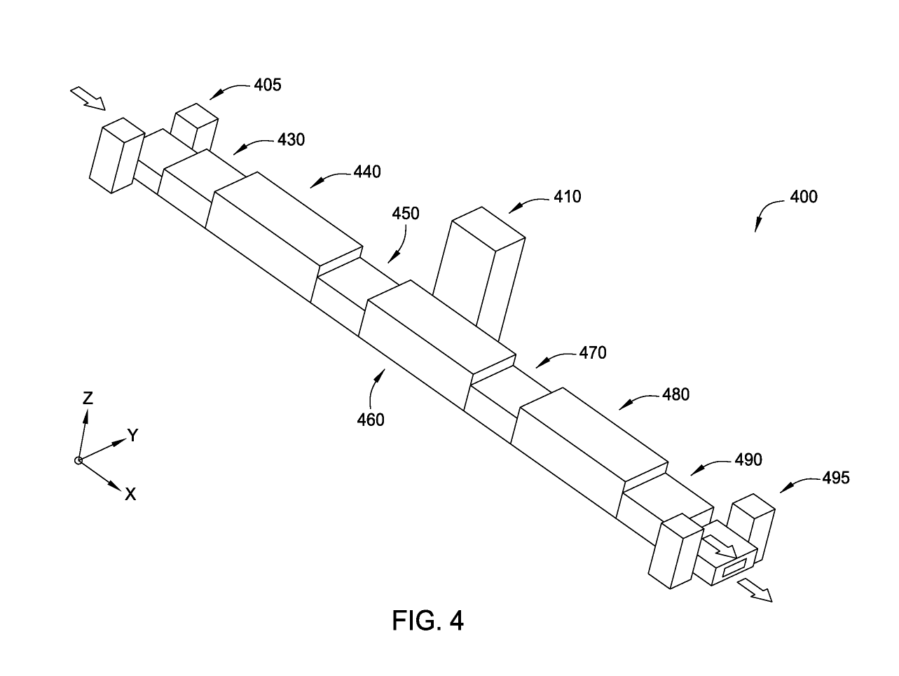

In one example, the formed solar cell device 300 comprises a passivation layer stack 140, such as an anti-reflective coating (ARC), and a rear surface passivation layer stack 120 that each contain at least two or more layers of deposited material that are all formed on the substrate 110 in the processing system 400 (FIG. 4). The substrate 110 may comprise single crystal silicon, multi-crystalline silicon, or polycrystalline silicon, but may also be useful for substrates comprising germanium (Ge), gallium arsenide (GaAs), cadmium telluride (CdTe), cadmium sulfide (CdS), copper indium gallium selenide (GIGS), copper indium selenide (CuInSe2), gallilium indium phosphide (GaInP2), organic materials, as well as heterojunction cells, such as GaInP/GaAs/Ge or ZnSe/GaAs/Ge substrates, that are used to convert sunlight to electrical power. The passivation/ARC layer stack 140 may comprise a first dielectric layer 115 that is in contact with the substrate surface 105, an interlayer 119 disposed over the first dielectric layer 115, and a second dielectric layer 117 that is disposed on the interlayer 119 as described with regard to FIGS. 1A-1C and FIG. 2. In one embodiment of the solar cell device 300, the selection of the passivation/ARC layer stack 140 and a rear surface passivation layer stack 120 will minimize the front surface reflection R₁ and maximize the rear surface reflection R₂ in the formed device, respectively, to improve the efficiency of the solar cell device 300.

In some embodiments, the use of the interlayer 119 reduces the required thickness of the underlying first dielectric layer 115 needed to form the passivation layer stack(s) 120 and 140, since the interlayer 119 provides properties, such as those described above, that are similar to or complement the passivation layer properties of the first dielectric layer 115. Use of the interlayer 119 and optimized first dielectric layer 115 can be beneficial when expensive materials such as aluminum oxides are used to form the first dielectric layer 115. Silicon oxide and silicon oxynitride containing layers, which may be used as the interlayer 119, are relatively cheaper to manufacture as compared to the aluminum oxide containing layers. It should be noted that the aluminum oxide containing layer is generally useful to help form a high efficiency silicon (Si) solar cell, because the aluminum oxide provides back surface passivation that provides for increased overall efficiency of the Si solar cell. Therefore, the required thickness of the often expensive to produce aluminum oxide containing layer used to form the dielectric layer 115 can be reduced because the interlayer 119 acts as a barrier layer between the dielectric layers 115 and 117. The interlayer 119 can also enhance the passivating effect or passivation performance of the underlying dielectric layer 115 through stress and/or charge modulation due to the fact that the interlayer 119 possesses low stress and low density of fixed charge.

Also, by selecting an interlayer 119 material that has desirable electrical, physical and/or passivating properties, the amount of aluminum oxide that is required to form the solar cell device can be reduced. The reduction in the amount or thickness of the aluminum oxide layer used to form the dielectric layer 115 also minimizes the difficulties associated with laser ablation of the passivation layer stack and improves the ability to form reliable electrical contacts and a BSF through the laser ablated features, due to the increase the accuracy and precision of the laser ablation process. Also, the optical properties of silicon dioxide and silicon oxynitride, such as refractive index, are close to that of a dielectric layer 115 that comprises aluminum oxide (n≈1.7). One will note that the laser ablation process is strongly dependent on the wavelength of the laser and the optical properties of the material(s) that are being ablated. Materials with similar optical properties may be more precisely ablated, which provides a cleaner and more repeatable ablated feature shape. Additionally, due to the properties of the interlayer 119 material and by adjusting its thickness and/or the thicknesses of the dielectric layers 115 and/or 117, within the passivation layer stack(s) 120 and/or 140, the red (e.g., long wavelengths (i.e., >˜1000 nm)) and/or blue (e.g., short wavelengths (i.e., <˜600 nm)) optical absorption of the formed solar cell device can be optimized to improve the solar cell's conversion efficiency.

Further, the interlayer 119 can act as a buffer to reduce charge instability between the first dielectric layer 115, which has a high density of negative charge (approximately −1 E13 cm⁻²), and the second dielectric layer 117, which has a high density of positive charge (approximately +2E13 cm⁻²). The interlayer 119 also acts as a buffer to reduce mechanical stress instability between the first dielectric layer 115, which often exhibits a low tensile stress (+0.01 GPa), and the second dielectric layer 117, which often exhibits a high compressive stress (−1 GPa). The interlayer 119 provides a better match to the first dielectric layer 115 versus the typical materials used to form the second dielectric layer 117 e.g., silicon nitride) by exhibiting a low positive charge and a low tensile/compressive stress, which results in improved thermal, charge, and stress stability. Finally, the interlayer 119 acts as a barrier for moisture and organic or metallic contamination transfer between the first dielectric layer 115 and the second dielectric layer 117. As a result, performance and stability of the passivation layer stack(s) 120 and 140 are increased which leads to improved solar cell efficiency.

For example, increases in efficiency (%), open circuit voltage (Voc (mV)), and short circuit current (Jsc (mA/cm²)) can be achieved when utilizing a passivation layer stack containing an interlayer comprising silicon dioxide, which is disposed between a first dielectric layer and a second dielectric layer. As a baseline, the inventors determined that an industrial screen-printed aluminum back-surface field (SP Al-BSF) provided a solar cell with an efficiency of 18.49%, Voc=640, and Jsc=36.4. A passivation stack formed from a first dielectric layer of aluminum oxide and a second dielectric layer of silicon nitride provided increases over the baseline in efficiency (+0.3%), Voc (+6), and Jsc (+0.7). However, a passivation layer stack, such as passivation layer stack 120, comprising a first dielectric layer of aluminum oxide, an interlayer of silicon dioxide, and a second dielectric layer of silicon nitride provided increases over the baseline in efficiency (+0.5%), Voc (+10), and Jsc (+0.9). As a result, the inventors have determined that the invention provides for improved performance and stability of the passivation layer stack and improved solar cell electrical characteristics, such as improved conversion efficiency.

The solar cell device, such as the solar cell device shown in FIG. 3, may be fabricated by performing the process steps of FIG. 2. FIG. 2 depicts a flow diagram illustrating a processing sequence of forming a solar cell device, such as solar cell device 300, according to the embodiments shown in FIGS. 1A-1C. It is noted that the processing sequences depicted in FIG. 2 are only used as one example of a process flow that can be used to manufacture a solar cell device. Some steps may be added, eliminated and/or reordered as needed to form a desirable solar cell device. The process sequence of FIG. 2 may be performed in a single substrate processing chamber, or in multiple substrate processing chambers provided in a cluster tool. One will note that, in some cases, each of the processes may be performed in an oxygen-free inert and/or vacuum environment, such as in the vacuum processing regions of a cluster tool, so that the substrate is not exposed to oxygen between the processes.

The method begins at step 210 by forming one or more passivation layer stack(s) 120 and 140 on a substrate having a light receiving surface and a back surface that is generally parallel and opposite to the light receiving surface on the substrate in a processing chamber. Generally, the substrate 110 is introduced into a processing chamber, such as a plasma enhanced chemical vapor deposition (PECVD) chambers, which are commercially available from Applied Materials, Inc. of Santa Clara, Calif. An example of a PECVD chamber design that may be adapted to perform one or more the processes described herein is disclosed in the commonly assigned provisional patent application Ser. No. 61/582,698, which is incorporated by reference herein. The substrate 110 generally has a base region 101, an emitter region 102, and a p-n junction region 103 disposed between the base region 101 and the emitter region 102, as shown in FIG. 1A. The substrate 110 may be a single crystal or multicrystalline silicon substrate, silicon containing substrate, doped (with p-type or n-type dopants) silicon containing substrate, or other suitable substrates. In one configuration, the substrate 110 is a p-type crystalline silicon (c-Si) substrate. P-type dopants used in silicon solar cell manufacturing are chemical elements, such as, boron (B), aluminum (Al) or gallium (Ga).

In another configuration, the substrate 110 may be an electronic grade silicon substrate or a low lifetime, defect-rich silicon substrate, for example, an upgraded metallurgical grade (UMG) crystalline silicon substrate. The upgraded metallurgical grade (UMG) silicon is a relatively clean polysilicon raw material having a low concentration of heavy metals and other harmful impurities, for example in the parts per million range, but which may contain a high concentration of boron or phosphorus, depending on the source. In certain applications, the substrate can be a back-contact silicon substrate prepared by emitter wrap through (EWT), metallization wrap around (MWA), or metallization wrap through (MWT) approaches. Although the embodiment depicted herein and relevant discussion thereof primarily discuss the use of a p-type c-Si substrate, this configuration is not intended to be limiting as to the scope of the invention, since an n-type c-Si substrate may also be used without deviating from the basic scope of the embodiments of the invention described herein. The doping layers or emitters formed over the substrate will vary based on the type of substrate that is used, as will be discussed below.

The substrate 110 has a light receiving surface (i.e., front surface 105) and a bottom or back surface 106 opposing the light receiving surface. The emitter region 102 may be an n-type emitter region formed by doping a deposited semiconductor layer with certain types of elements (e.g., phosphorus (P), arsenic (As), or antimony (Sb)) using any suitable techniques, such as an implant process (followed by an anneal process) or a thermal diffusion process using a phosphosilicate glass (PSG), in order to increase the number of negative charge carriers, i.e., electrons. The p-n junction region 103 is the region in which electron-hole pairs are generated when solar cell device 100 is illuminated by incident photons of light. In one embodiment, an anti-reflective coating, such as passivation ARC layer (not shown), may be deposited on the light receiving surface 105 of the solar cell device 100 when the substrate is passivated with the passivation layer stack 120 on the back surface. In this embodiment, the passivation ARC layer may include silicon oxide, silicon nitride or a combination thereof.

At step 220, a first dielectric layer 115 is formed on the back surface 106 of the base region 101 or the light receiving surface 105 of the substrate 110. At step 230, an interlayer 119 is formed over the first dielectric layer 115. At step 240, a second dielectric layer 117 is formed over the interlayer 119. The passivation layer stack(s) 120 and 140 formed by the first dielectric layer 115, the interlayer 119 and the second dielectric layer 117 provide good interface properties that reduce the recombination of the electrons and holes and drive and/or diffuse electrons and charge carriers. The first dielectric layer 115, interlayer 119, and second dielectric layers 117 may be fabricated from a dielectric material selected from the group consisting of silicon oxide (SiₓO_{y}), silicon nitride (SiₓN_{y}), silicon nitride hydride (SiₓN_{y}:H), silicon oxynitride (SiON), silicon oxycarbonnitride (SiOCN), silicon oxycarbide (SiOC), titanium oxide (TiₓO_{y}), tantalum oxide (TaₓO_{y}), lanthanum oxide (LaₓO_{y}), Hafnium oxide (HfₓO_{y}), titanium nitride (TiₓN_{y}), tantalum nitride (TaₓN_{y}), hafnium nitride (HfN), hafnium oxynitride (HfON), lanthanum nitride (LaN), lanthanum oxynitride (LaON), chlorinated silicon nitride (SiₓN_{y}:Cl), chlorinated silicon oxide (SiₓO_{y}:Cl), amorphous silicon, amorphous silicon carbide, aluminum oxide (AlₓO_{y}), aluminum nitrite, or aluminum oxynitride.

In one embodiment, passivation layer stack 120 is formed on the back surface 106 of the substrate 110. In this embodiment, the first dielectric layer 115 may comprise an aluminum oxide material, such as aluminum oxide (Al₂O₃) and the second dielectric layer 117 may comprise a silicon nitride material, such as silicon nitride (Si₃N₄). The interlayer 119 may comprise a silicon oxide material, such as a silicon dioxide (SiO₂) material. In another embodiment, passivation layer stack 140 is formed on the emitter/light receiving surface 105 of the substrate 110. In this embodiment, the first dielectric layer 115 may comprise an aluminum oxide material, such as an aluminum oxide (Al₂O₃) material and the second dielectric layer 117 may comprise a silicon nitride material, such as a silicon nitride (Si₃N₄) material. The interlayer 119 may comprise a silicon oxide or silicon oxynitride material, such as a silicon dioxide (SiO₂) or a silicon oxynitride (SiON) material. In either case, the first dielectric layer 115 may have a thickness of about 100 Å to about 300 Å and the second dielectric layer 117 may have a thickness of about 800 Å to about 1000 Å. The interlayer 119 may have a thickness of about 25 Å to about 300 Å, such as about 50 Å to about 100 Å. The total passivation layer stack 120 and 140 thickness may be about 925 Å to about 1600 Å.

An example of various deposition processes, such as processes developed on a PECVD passivation tool available from Applied Materials, Inc., that may be used to form the dielectric layers 115 and 117 and the interlayer 119 with the desired properties in the passivation layer stack(s) 120 and 140 will now be discussed. The first dielectric layer 115 may be formed by introducing a first process gas mixture into a process volume of a first PECVD processing chamber and generating a plasma in the process volume. In one embodiment, the first dielectric layer 115 comprises aluminum oxide (Al₂O₃). An aluminum-containing gas, such as trimethylaluminum (TMA), may be flowed into the PECVD processing chamber at a flow rate of about 20 sccm to about 130 sccm, and an oxygen-containing gas, such as oxygen (O₂) or nitrous oxide (N₂O), may be flowed into the PECVD processing chamber at a flow rate of about 300 sccm to about 1400 sccm. The aluminum-containing gas and the oxygen-containing gas may be introduced into the chamber at a ratio of between about 1:1 and about 1:15. The chamber pressure may be maintained between about 2 mTorr and about 20 mTorr, with an AC power of about 3000 W to about 6000 W, at a frequency of 40 KHz, and a substrate support temperature of between about 250° C. and about 400° C. The AC power for the first dielectric layer deposition may generate a plasma for a period of time of about 10 seconds to about 45 seconds. The first dielectric layer 115 may be deposited at 250 Å or more per minute, such as about 500 Å/min. The formed first dielectric layer 115 may have a thickness between about 50 Å and 1,000 Å, such as between about 100 Å and about 450 Å. It is contemplated that the first dielectric layer 115 may be deposited using any suitable deposition techniques, for example, a chemical vapor deposition (CVD), an atomic layer deposition (ALD) process, or a physical vapor deposition (PVD) process.

Once the first dielectric layer 115 has been formed on the light receiving surface 105 or the back surface 106 of the substrate 110, the interlayer 119 may be formed over the first dielectric layer 115. The interlayer 119 may be formed in-situ within the same PECVD chamber used to deposit the first dielectric layer 115 to avoid vacuum break between the deposition of the first dielectric layer 115 and the interlayer 119. In certain embodiments, the interlayer 119 may be formed ex-situ in a chamber not within the processing system 400 contemplated to perform in-situ deposition. The interlayer 119 may be formed by introducing a gas mixture into the process volume of the PECVD processing chamber and generating a plasma in the process volume.

In embodiments where the interlayer 119 is silicon dioxide (SiO₂), the first process gas mixture may comprise a silicon-containing gas, an oxidizing gas and/or a carrier gas (e.g., helium). The silicon-containing gas may be selected from a group consisting of silane, disilane, chlorosilane, dichlorosilane, trichlorosilane, dibromosilane, trimethylsilane, tetramethylsilane, tridimethylaminosilane (TriDMAS), tetraethoxysilane (TEOS), triethoxyfluorosilane (TEFS), silicon tetrachloride, silicon tetrabromide, 1,3,5,7-tetramethylcyclotetrasiloxane (TMCTS), dimethyldiethoxy silane (DMDE), octomethylcyclotetrasiloxane (OMCTS), methyldiethoxysilane (MDEOS), bis(tertiary-butylamino)silane (BTBAS), or combinations thereof. The oxidizing gas may be selected from the group consisting of consisting of oxygen (O₂), nitrous oxide (N₂O), ozone (O₃), and combinations thereof.

In embodiments where the interlayer 119 is silicon oxynitride (SiON), the first process gas mixture may comprise a silicon-containing gas, an oxidizing gas, a nitrogen-containing gas, and/or a carrier (e.g. helium). The silicon-containing gas and the oxidizing gas may be selected from the listing of gases described above with regard to forming the silicon dioxide interlayer. Additionally, the nitrogen-containing gas may be selected from nitrogen (N₂) or ammonia (NH₃). In certain embodiments, the silicon oxynitride interlayer 119 of stack 140 on the light receiving surface 105 of the substrate 110 may be deposited by a second PECVD chamber which is discussed below.

During deposition of the silicon dioxide, the silicon-containing gas may be flowed into the PECVD processing chamber, such as the AKT 4300 PECVD tool available from Applied Materials, Inc., at a flow rate of about 0.15 standard cubic centimeter per minute per liter (sccm/L) to about 7 sccm/L, and the oxidizing gas may be flowed into the processing chamber at a flow rate of about 4 sccm/L to about 100 sccm/L. The silicon-containing gas may be silane and the oxidizing gas may be ozone. The ratio of the oxidizing gas to the silicon-containing gas may be from about 200:1 to about 10:1, such as about 100:1 to about 30:1, for example 50:1. The chamber pressure may be between about 0.2 Torr and about 10 Torr, such as between about 0.5 Torr and about 2 Torr. The electrode spacing (i.e., a distance between a showerhead and a substrate support) may be maintained between about 400 mils and about 2000 mils. For processing a 600 mm×720 mm substrate, or similar sized substrate carrier containing a plurality of smaller substrates (e.g., ˜12 substrates (i.e., 156 mm×156 mm substrates)), the plasma may be provided by RF power from about 50 W to about 5000 W, such as about 2000 W, at a frequency of 13.56 MHz. The RF power for the first dielectric layer deposition may generate a plasma for a period of time of about 10 seconds to about 360 seconds. The interlayer 119 may be deposited at 80 angstroms (Å) per minute to about 800 Å per minute, such as about 500 Å/min, and at a substrate support temperature of between about 250° C. and about 450° C. The formed interlayer 119 may have a thickness between about 25 Å and 1,000 Å, such as between about 50 Å and about 100 Å.

In step 240, the second dielectric layer 117 is deposited on the interlayer 119. The second dielectric layer 117 may be formed in-situ within the same processing system 400 (FIG. 4) used to deposit the first dielectric layer 115 and the interlayer 119 to avoid a vacuum break between the deposition steps. However, in certain embodiments, the second dielectric layer 117 may be formed in a second processing chamber, such as a second PECVD chamber, which is positioned downstream of the first PECVD chamber and, in one example, may be disposed a distance in the processing system 400 from the first PECVD chamber. An exemplary processing system 400 is discussed hereinafter. The second dielectric layer 117 (or interlayer 119 comprising silicon oxynitride) may be formed by introducing a second process gas mixture into the process volume of the second PECVD processing chamber and generating a plasma in the process volume.

In cases where the second dielectric layer 117 comprises a silicon nitride, such as silicon nitride (Si₃N₄), the second process gas mixture may comprise a silicon-containing gas, a nitrogen-containing gas and/or a carrier gas. For example, the second process gas mixture may be a combination of silane (SiH₄) and nitrogen (N₂), silane and ammonia (NH₃), or silane, ammonia, and nitrogen. The silicon-containing gas may also be one of those mentioned above with respect to the first dielectric layer 115. If desired, a hydrogen gas may be flowed along with the second process gas mixture. In certain embodiments, the silicon oxynitride interlayer 119 may be deposited in the second PECVD chamber in which case an oxidizing gas selected from the group consisting of oxygen (O₂), nitrous oxide (N₂O), ozone (O₃), and combinations thereof may be provided in addition to the silicon-containing gas and nitrogen-containing gas.

During deposition of the silicon nitride, the silicon-containing gas may be flowed into the PECVD processing chamber, such as the AKT 5500 PECVD tool available from Applied Materials, Inc., at a flow rate of about 1 sccm/L to about 5 sccm/L, and the nitrogen-containing gas may be flowed into the PECVD processing chamber at a flow rate of about 5 sccm/L to about 100 sccm/L. The ratio of the nitrogen-containing gas to the silicon-containing gas may be from about 5:1 to about 15:1, such as about 10:1. The chamber pressure may be between about 0.5 Torr and about 5 Torr. The electrode spacing may be maintained between about 400 mils and about 2000 mils. For processing a 730 mm×920 mm substrate, or similar sized substrate carrier containing a plurality of substrates (e.g., ˜20 substrates (i.e., 156 mm×156 mm substrates)), the plasma may be provided by an RF power of about 500 W to about 6000 W, at a frequency of 13.56 MHz. The RF power for the first dielectric layer deposition may generate a plasma for a period of time of about 20 seconds to about 600 seconds. To further densify the second dielectric layer 117, a substrate bias power may be applied to effectuate ion bombardment on the surface of the second dielectric layer 117. In such a case, the substrate bias power may be between about 0.02 W/cm² and about 1.0 W/cm². The second dielectric layer 117 may be deposited at 250 Å or more per minute, such as about 1500 Å/min, and at a substrate support temperature of between about 350° C. and about 650° C. The formed second dielectric layer 117 may have a thickness between about 350 Å and 900 Å, such as between about 600 Å and about 800 Å. In various embodiments, the passivation layer stack(s) 120 and 140 may have a total thickness between about 950 Å and 1400 Å.

FIG. 4 is a schematic isometric view of one embodiment of a substrate processing system according to certain embodiments of the present invention. The present invention generally provides a high throughput substrate processing system 400, or cluster tool, for in-situ processing of a film stack used to form regions of a solar cell device. In one configuration, one or more film stacks formed on each of the substrates contains one or more passivating or dielectric layers that are deposited and further processed within one or more processing chambers contained within the high throughput substrate processing system 400. The processing chambers may be, for example, plasma enhanced chemical vapor deposition (PECVD) chambers, low pressure chemical vapor deposition (LPCVD) chambers, atomic layer deposition (ALD) chambers, physical vapor deposition (PVD) chambers, thermal processing chambers (e.g., RTA or RTO chambers), substrate reorientation chambers (e.g., flipping chambers) and/or other similar processing chambers.

The high throughput substrate processing system 400 may include one or more deposition chambers in which substrates are exposed to one or more gas-phase materials and an RF plasma. In one embodiment, the processing system 400 includes at least one plasma enhanced chemical vapor deposition (PECVD) processing chamber that has been adapted to simultaneously process a plurality of substrates as they pass through the system 400 in a linear direction. In one embodiment, solar cell substrates are simultaneously transferred in a vacuum or inert environment through the linear system 400 to prevent substrate contamination and improve substrate throughput. In certain embodiments, the substrates are arranged in a linear array for processing as opposed to processing vertical stacks of substrates (e.g., batches of substrates stacked in cassettes) or planar arrays of substrates that are typically transferred on a substrate carrier in a batch. Such processing of substrates arranged in linear arrays allows each of the substrates to be directly and uniformly exposed to the generated plasma, radiant heat, and/or processing gases. The linear array may contain sub-sets or groups of the substrates that are similarly processed as they are serially transferred through the processing system. In this configuration, the sub-sets or groups of substrates are generally substrates disposed in the linear array that are similarly aligned in a direction perpendicular to the substrate transfer direction, and thus will be similarly processed at any given time during the processing sequence. Thus, processing groups of substrates that are disposed in linear arrays does not rely on diffusion type processes or the serial transfer of energy from one substrate to the next, such as undesirably found in conventionally configured vertical stack or back-to-back batch substrate processing.

Embodiments of the invention disclosed herein can be used to rapidly form the next generation solar cell devices in a high throughput substrate processing system 400. In some configurations, the next generation solar cell devices will contain multiple deposited layers, such as advanced passivation layers (i.e. passivation layer stacks 120 and 140), that are formed on both sides of a solar cell substrate in the processing system 400. As noted above, forming layers, such as high quality passivation layers, on both sides of the substrate can reduce carrier recombination, redirect electrons and holes back into the solar cells to generate a desirable photocurrent, and act as a rear side reflector to better collect the incident solar energy. However, as one skilled in the art will appreciate, the ability of a processing system to form and process multiple layers on both sides of a substrate, while maintaining a high substrate throughput (e.g., >3000 substrates per hour) and provide a repeatable and desirable film quality has been elusive for the solar cell fabrication industry. The processing system configurations described herein are thus generally configured to reliably form a high quality advanced passivation layer on both surfaces of a solar cell substrate.

In one embodiment, the substrate processing system 400 may include a substrate receiving chamber 405, pre-processing chamber 430, at least one processing chamber maintained at a pressure below that of atmospheric pressure, such as a first processing chamber 440, a second processing chamber 460, and a third processing chamber 480, at least one transferring chamber, such as transferring chambers 450 and 470, a buffer chamber 490 and a substrate unload chamber 495. Collectively, the processing chambers 430-490 may include one of the following types of chambers PECVD chambers, LPCVD chambers, hot wire chemical vapor deposition (HWCVD) chambers, ion implant/doping chambers, plasma nitridation chambers, atomic layer deposition (ALD) chambers, physical vapor deposition (PVD) or sputtering chambers, plasma or vapor chemical etching chambers, thermal processing chambers (e.g., RTA or RTO chambers), substrate reorientation chambers (e.g., flipping chambers) and/or other similar processing chambers. Further description of an advanced platform for passivating crystalline silicon solar cells that may be used by embodiments herein is disclosed in commonly assigned U.S. patent application Ser. No. 61/582,698, filed on Jan. 3, 2012, which is hereby incorporated by reference in its entirety to the extent not inconsistent with the claimed invention.

In certain embodiments, the process may proceed by processing substrates in a first processing chamber 440 and a second processing chamber 460, flipping the substrates in a substrate reorientation chamber, and further processing the substrate in a third processing chamber similar to the first processing chamber, and a fourth processing chamber similar to the second processing chamber. In this embodiment, passivation layer stacks may be formed on both the light receiving surface of the substrates and the back surface of the substrates. It is contemplated that other processing sequences may be performed to achieve the desired passivation layer stack deposition and the aforementioned embodiment should not be construed as limiting the invention.

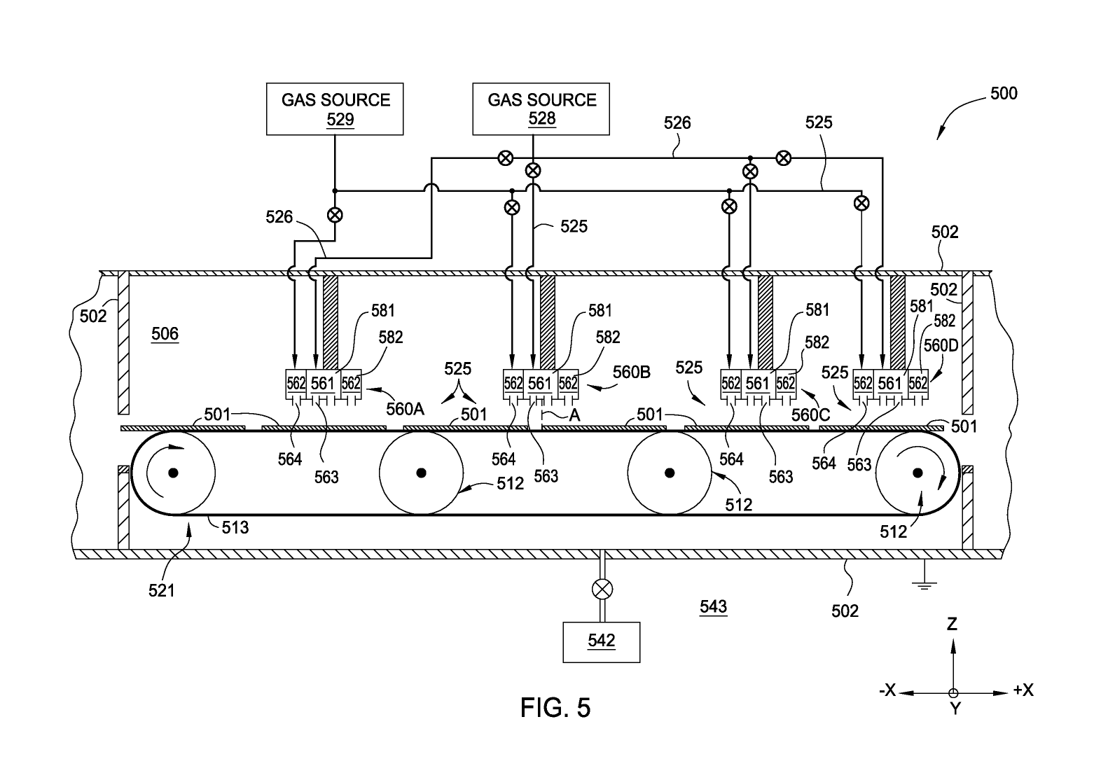

FIG. 5 is a schematic side cross-sectional view of a deposition chamber according to certain embodiments of the present invention. The processing chamber 500 may be positioned within or replace one or more of the processing chambers, such as chambers 440, 460, and 480, disposed in the processing system 400. In one embodiment, the processing chamber 500 comprises one or more deposition sources, such as deposition sources 560A-560D, gas sources 528 and 529, a power source 530, chamber walls 502 that at least partially enclose a portion of the processing region 506, and at least a portion of the substrate automation system 515, such as a conveyor transfer system. Deposition sources 560A-D are intended to form a layer on the surface of the substrates 501 as they pass under the deposition sources. The walls 502 generally comprise a material that can structurally support the loads applied by the environment 543, which is external to the processing region 506, when it is heated to a desirable temperature and pumped to a vacuum pressure by a vacuum pump 542. The walls 502 generally comprise a material such as an aluminum material or stainless steel.

In one configuration, the portion of the substrate automation system 515 comprises a conveyor 521 that is adapted to support, guide move the substrates 501 through the processing chamber 500 by use of one or more actuators (not shown), for example, a stepper motor or servo motor. In one configuration, the conveyor 521 comprises a two or more rollers 512 and a belt 513 that are configured to support and move the rows of substrates 501 in a positive +X-direction during processing.

In one embodiment of the processing chamber 500, each of the deposition sources 560A-560D are coupled to at least one gas source, such as gas sources 528 and 529, that is configured to deliver one or more processing gases to a processing region 525 formed with the processing region 506, and below each of the deposition sources 560A-D and over the surface of a substrate 501 disposed there under.

The deposition sources 560A-D, will generally comprise at least one gas delivery element, such as a first gas delivery element 581 and second gas delivery element 582, which are each configured to direct the processing gases to the processing region 525. The first gas delivery element 581 comprises a fluid plenum 561 that is configured to receive the process gas from a gas source 528 and deliver the received gas to the processing region 525 through a plurality of holes 563 formed therein. Similarly, the second gas delivery element 582 comprises a fluid plenum 562 that is configured to receive the process gas from a gas source 529 and deliver the received gas to the processing region 525 through a plurality of holes 564 formed therein. The gas sources 528 and 529 are generally configured to provide one or more precursor gases and/or carrier gases that are used to deposit a layer on the surface of the substrates 501 by use of a PECVD process.

In one process sequence, such as processing performed in a first processing chamber 440, at least one of the gas sources 528 and 529 is configured to deliver an aluminum-containing gas to the deposition sources 560A-D, such as trimethylaluminum (TMA), and an oxygen-containing gas to a deposition source 560A-D. The oxygen-containing gas may be selected from a group consisting of oxygen (O₂), nitrous oxide (N₂O), ozone (O₃), and combinations thereof. In one embodiment, the aluminum-containing gas is TMA and the oxygen-containing gas is O₂. The aluminum-containing gas and the oxygen-containing gas may form the first dielectric layer 115 on the surface of the substrates 501.

In another process sequence, such as processing performed in a first processing chamber 440, at least one of the gas sources 528 and 529 is configured to deliver a silicon-containing gas and an oxygen containing gas to a deposition source 560A-D. The oxygen-containing gas may be selected from a group consisting of oxygen (O₂), nitrous oxide (N₂O), ozone (O₃), and combinations thereof. The silicon-containing gas may be selected from a group consisting of silane, disilane, chlorosilane, dichlorosilane, trichlorosilane, dibromosilane, trimethylsilane, tetramethylsilane, tridimethylaminosilane (TriDMAS), tetraethoxysilane (TEOS), triethoxyfluorosilane (TEFS), silicon tetrachloride, silicon tetrabromide, 1,3,5,7-tetramethylcyclotetrasiloxane (TMCTS), dimethyldiethoxy silane (DMDE), octomethylcyclotetrasiloxane (OMCTS), methyldiethoxysilane (MDEOS), bis(tertiary-butylamino)silane (BTBAS), or combinations thereof. In one embodiment, the silicon-containing gas is silane and the oxygen-containing gas is N₂O. The silicon-containing gas and oxygen-containing gas form the interlayer 119 of silicon dioxide over the first dielectric layer 115.

In certain embodiments, a processing chamber such as a first processing chamber 440, may deposit the first dielectric layer 115 and the interlayer 119 of silicon dioxide. In this embodiment, the process chamber 500 may be depositing layers on the light receiving surface and/or the back surface of the substrate 501. It is contemplated that any of deposition sources 560A-D may be configured to deliver an aluminum-containing gas, an oxygen-containing gas, and a silicon-containing gas to achieve desired passivation layer stack deposition. It is also contemplated that more gas sources may be added to the chamber 500 to accommodate more types of gas delivery.

In one process sequence, such as processing performed in a second processing chamber 460, at least one of the gas sources 528 and 529 is configured to deliver a silicon-containing gas to a deposition source 560A-D and an nitrogen-containing gas to the deposition sources 560A-D. The silicon-containing gas may be selected from the group consisting of silane, disilane, chlorosilane, dichlorosilane, trichlorosilane, dibromosilane, trimethylsilane, tetramethylsilane, tridimethylaminosilane (TriDMAS), tetraethoxysilane (TEOS), triethoxyfluorosilane (TEFS), silicon tetrachloride, silicon tetrabromide, 1,3,5,7-tetramethylcyclotetrasiloxane (TMCTS), dimethyldiethoxy silane (DMDE), octomethylcyclotetrasiloxane (OMCTS), methyldiethoxysilane (MDEOS), bis(tertiary-butylamino)silane (BTBAS), or combinations thereof. The nitrogen-containing gas may be selected from the group consisting of nitrogen (N₂) or ammonia (NH₃). In one embodiment, the silicon-containing gas is silane and the nitrogen containing gas is either N₂ or NH₃. The silicon-containing gas and the nitrogen-containing gas form the second dielectric layer 117 on the interlayer 119.

In another process sequence, such as processing performed in a second processing chamber 460, at least one of the gas sources 528 and 529 is configured to deliver a silicon-containing gas, an oxygen containing gas, and a nitrogen-containing gas to a deposition source 560A-D. The silicon-containing gas may be selected from a group consisting of silane, disilane, chlorosilane, dichlorosilane, trichlorosilane, dibromosilane, trimethylsilane, tetramethylsilane, tridimethylaminosilane (TriDMAS), tetraethoxysilane (TEOS), triethoxyfluorosilane (TEFS), silicon tetrachloride, silicon tetrabromide, 1,3,5,7-tetramethylcyclotetrasiloxane (TMCTS), dimethyldiethoxy silane (DMDE), octomethylcyclotetrasiloxane (OMCTS), methyldiethoxysilane (MDEOS), bis(tertiary-butylamino)silane (BTBAS), or combinations thereof. The oxygen-containing gas may be selected from a group consisting of oxygen (O₂), nitrous oxide (N₂O), ozone (O₃), and combinations thereof. The nitrogen containing gas may be selected from a group consisting of nitrogen (N₂) or ammonia (NH₃) In one embodiment, the silicon-containing gas is silane, the oxygen-containing gas is N₂O, and the nitrogen-containing gas is either N₂ or NH₃. The silicon-containing gas, oxygen-containing gas, and nitrogen containing gas form the interlayer 119 of silicon oxynitride over the first dielectric layer 115.

In certain embodiments, a processing chamber such as a second processing chamber 460, may deposit the second dielectric layer 117 and the interlayer 119 of silicon oxynitride. In this embodiment, the process chamber 500 may be depositing the interlayer 119 on the light receiving surface of the substrate 501. The process chamber 500 may also deposit the second dielectric layer 117 over the interlayer 119 on either the light receiving surface or the back surface. It is contemplated that any of deposition sources 560A-D may be configured to deliver a silicon-containing gas, a nitrogen-containing gas, and a nitrogen-containing gas to achieve desired passivation layer stack deposition. It is also contemplated that more gas sources may be added to the chamber 500 to accommodate more types of gas delivery.

While the foregoing is directed to embodiments of the present invention, other and further embodiments of the invention may be devised without departing from the basic scope thereof, and the scope thereof is determined by the claims that follow.

1. A solar cell device, comprising:
an emitter region formed on a first surface of a substrate, the emitter region having a conductivity type opposite to a conductivity type of the substrate; and
one or more passivation layer stacks, comprising:
a first dielectric layer formed on a second surface of the substrate or the emitter region;
a second dielectric layer formed over the first dielectric layer; and
an interlayer disposed between the first dielectric layer and the second dielectric layer.

2. The solar cell device of claim 1, wherein the first dielectric layer, the second dielectric layer and the interlayer are fabricated from a material selected from the group consisting of silicon oxide (SiₓO_{y}), silicon nitride (SiₓN_{y}), silicon nitride hydride (SiₓN_{y}:H), silicon oxynitride (SiON), silicon oxycarbonnitride (SiOCN), silicon oxycarbide (SiOC), titanium oxide (TiₓO_{y}), tantalum oxide (TaₓO_{y}), lanthanum oxide (LaₓO_{y}), Hafnium oxide (HfₓO_{y}), titanium nitride (TiₓN_{y}), tantalum nitride (TaₓN_{y}), hafnium nitride (HfN), hafnium oxynitride (HfON), lanthanum nitride (LaN), lanthanum oxynitride (LaON), chlorinated silicon nitride (SiₓN_{y}:Cl), chlorinated silicon oxide (SiₓO_{y}:Cl), amorphous silicon, amorphous silicon carbide, aluminum oxide (AlₓO_{y}), aluminum nitrite, or aluminum oxynitride.

3. The solar cell device of claim 2, wherein the first dielectric layer comprises aluminum oxide (Al₂O₃).

4. The solar cell device of claim 3, wherein the interlayer comprises either silicon dioxide (SiO₂) or silicon oxynitride (SiON).

5. The solar cell device of claim 3, wherein the second dielectric layer comprises silicon nitride (SiNₓ) and wherein the interlayer comprises either silicon dioxide (SiO₂) or silicon oxynitride (SiON).

6. The solar cell device of claim 1, wherein the one or more passivation layer stacks is disposed on a second surface of the substrate and the interlayer comprises silicon dioxide, wherein the second surface of the substrate is opposite to the first surface.

7. The solar cell device of claim 1, wherein the one or more passivation layer stacks is disposed over the first surface of the substrate.

8. The solar cell device of claim 1, wherein the one or more passivation layer stacks has a total thickness of about 950 Å to about 1400 Å, and wherein the first dielectric layer has a thickness of about 100 Å to about 300 Å, the second dielectric layer has a thickness of about 800 Å to about 1000 Å, and the interlayer has a thickness of about 50 Å to about 100 Å.

9. A method of manufacturing a solar cell device, comprising:
forming one or more passivation layer stacks on a first surface of a substrate in one or more processing chambers, comprising:
forming a first dielectric layer comprising aluminum oxide on the first surface of the substrate;
forming an interlayer over the first dielectric layer; and
forming a second dielectric layer comprising silicon nitride over the interlayer.

10. The method of claim 9, wherein the interlayer is fabricated from a material selected from the group consisting of silicon oxide (SiₓO_{y}), silicon nitride (SiₓN_{y}), silicon nitride hydride (SiₓN_{y}:H), silicon oxynitride (SiON), silicon oxycarbonnitride (SiOCN), silicon oxycarbide (SiOC), titanium oxide (TiₓO_{y}), tantalum oxide (TaₓO_{y}), lanthanum oxide (LaₓO_{y}), hafnium oxide (HfₓO_{y}), titanium nitride (TiₓN_{y}), tantalum nitride (TaₓN_{y}), hafnium nitride (HfN), hafnium oxynitride (HfON), lanthanum nitride (LaN), lanthanum oxynitride (LaON), chlorinated silicon nitride (SiₓN_{y}:Cl), chlorinated silicon oxide (SiₓO_{y}:Cl), amorphous silicon, amorphous silicon carbide, aluminum oxide (AlₓO_{y}), aluminum nitrite, or aluminum oxynitride.

11. The method of claim 10, wherein the interlayer comprises either silicon dioxide (SiO₂) or silicon oxynitride (SiON).

12. The method of claim 11, wherein the first surface is a back surface of the substrate and wherein the interlayer comprises silicon dioxide.

13. The method of claim 11, wherein the one or more passivation layer stacks is disposed on the light receiving surface of the substrate and wherein the interlayer comprises either silicon dioxide or silicon oxynitride.

14. The method of claim 9, wherein the one or more passivation layer stacks has a total thickness of about 800 Å to about 1100 Å, and wherein the first dielectric layer has a thickness of about 100 Å to about 300 Å, the second dielectric layer has a thickness of about 800 Å to about 1000 Å, and the interlayer has a thickness of about 50 Å to about 100 Å.

15. A solar cell processing system, comprising:
a substrate automation system having one or more conveyors that are configured to transfer substrates serially through a processing region in a first direction, wherein the processing region is maintained at a pressure below atmospheric pressure;
a first processing chamber having a first deposition source configured to deliver a processing gas comprising an aluminum containing precursor and an oxygen containing precursor to a surface of each of the substrates and a second deposition source configured to deliver a silicon containing precursor and an oxygen containing precursor to a surface of each of the substrates as the substrates are transferred through the processing region relative to the two or more first deposition sources; and
a second processing chamber having a first deposition source configured to deliver a processing gas comprising a silicon containing precursor, a nitrogen containing precursor and an oxygen containing precursor to the surface of each of the substrates as the substrates are transferred through the processing region relative to the first deposition source.

16. The solar cell processing system of claim 15, wherein the first deposition source is further configured to deliver a silicon containing precursor.

17. The solar cell processing system of claim 16, wherein the second deposition source is further configured to deliver a silicon containing precursor and an oxygen containing precursor.

18. The solar cell processing system of claim 15, wherein the first deposition source is configured to deliver a silicon containing precursor and a nitrogen containing precursor.

19. The solar cell processing system of claim 18, wherein the second deposition source is configured to deliver a silicon containing precursor, an oxygen containing precursor, and a nitrogen containing precursor.

20. The solar cell processing system of claim 15, wherein the first processing chamber and the second processing chamber are positioned in a linear alignment.
